(19) United States
(12) Patent Application Publication
(10) Pub. No.: US 2014/0352618 A1
(43) Pub. Date: Dec. 4, 2014

(54) SYSTEM FOR FORMING GRAPHENE ON SUBSTRATE

(71) Applicant: XUESONG LI, Wappingers Falls, NY (US)

(72) Inventor: XUESONG LI, Wappingers Falls, NY (US)

(21) Appl. No.: 13/909,104

(22) Filed: Jun. 4, 2013

(51) Int. Cl. C23C 16/26

(52) U.S. Cl. CPC C23C 16/26
USPC 118/724

(57) ABSTRACT

A system for forming a graphene on a substrate includes a reactor having a gas inlet and a gas outlet; a substrate placed in a lower side of the reactor; a carbon-containing heating element located in reactor; which is exposed to the same gases with the substrate; the heating element being used as a heating source to heat the substrate and also as a carbon source for forming a graphene film on a substrate; at least one process gas inputted from the gas inlet; and after reaction, the process gas outputs from the gas outlet. The heating element is powered on by a power source and the heating element is heated; by controlling the feeding of process gas, small amount of carbon can be transported to the surface of the substrate for graphene growth; and thus, a graphene sheet is formed on the substrate.

### FIELD OF THE INVENTION

The present invention is related to graphene, and in particular to a system for forming graphene on a substrate

### BACKGROUND OF THE INVENTION

Graphene is a one-atom-thick sheet of sp2-bonded carbon arranged in a regular hexagonal pattern. Graphene is presently the target of intense study because it has many interesting and useful mechanical, optical, and electrical properties. Graphene can exhibit very high electron- and hole-mobilities. One remarkable property of graphene is that when electrons move therein, the electrons move as if the mass of the electrons is zero. This means that the electrons move at a speed as light travels in vacuum, that is, at the speed of light. Graphene exhibits an abnormal half-integer quantum Hall effect with respect to electrons and holes, and also has a high electron mobility ranging from about 20,000 to about 50,000 cm.sup.2/Vs. As a result, it may allow graphene-based electronic devices to display extremely high switching speeds. Graphene may also be used as an electrode material for power storage devices and displays, as a membrane material in electromechanical systems, as a membrane for the separation of gases, as a chemical sensor, and in a myriad of other applications.

Graphene has attracted great research interests due to their superior properties. And the synthesis of graphene films on copper (Cu) foils by chemical vapor deposition (CVD) technique provides a promising way for large-area graphene production (X S Li et al. Science 5 Jun. 2009, Vol. 324 no. 5932 pp. 1312-131). This method requires hydrocarbon as carbon source, which is usually flammable and explosive, and thus has safety concerns.

Traditionally, graphene is synthesized in a quartz chamber, which insulates the reaction environment from heating elements. This method uses graphite or other carbon or carbon-containing filaments as heating elements, which exposes to the same atmosphere with the metal substrate. By controlling the feeding of reactant gas, which may react with carbon, small amount of carbon can be transported to metal surface for graphene growth. Power source can be DC or AC. AC frequencies ranges from 1 to 10 GHz.

Presently, high quality graphene can be formed by the repeated mechanical exfoliation of graphite. Nevertheless, graphene produced by this method tends to be limited in size. As a result, researchers have studied the chemical vapor deposition (CVD) of graphene as an alternative method of synthesis. U.S. Patent Publication No. 2011/0091647, to Colombo et al. and entitled “Graphene Synthesis by Chemical Vapor Deposition,” for example, teaches the CVD of graphene on metal and dielectric substrates using hydrogen and methane in a CVD tube reactor. Even so, there remain concerns that known CVD techniques, while being able to produce graphene films larger than those that can be formed by graphite exfoliation, may produce graphene films with qualities inferior to those found in exfoliated films. Moreover, there remain concerns about utilizing gaseous carbon sources such as methane when forming graphene by high-temperature CVD because of the risks of explosion.

Another disadvantage of current CVD equipment by using quartz tube as reaction chamber is that with the chamber size increase the manufacture difficulty and cost increase dramatically.

As a result, there is an eager need for improved apparatus for the formation of high quality graphene by CVD.

### SUMMARY OF THE INVENTION

Accordingly, the object of the present invention is to provide a system for forming graphene on a substrate which is useful for forming large area graphene film easily and safely.

To achieve above object, the present invention provides a system for forming graphene on a substrate including a reactor having a gas inlet and a gas outlet; a substrate placed in a lower side of the reactor; a carbon-containing heating element located in reactor; which is exposed to the same atmosphere with the substrate; the heating element being used as a heating source to heat the substrate and also as a carbon source for forming graphene film on a substrate; process gas inputted from the gas inlet and after reaction, the exhaust outputs from the gas outlet. The heating element is powered on by a power source; by controlling the feeding of process gases, very small amount of carbon can be transported to the surface of the substrate for graphene growth; and thus, a graphene sheet is formed on the substrate.

### BRIEF DESCRIPTION OF THE DRAWINGS

FIG. 1 shows the structure for forming a graphene film according to the present invention.

FIG. 2A illustrates an upper view of the heating element according to the present invention.

FIG. 2B shows a lateral side view of the carbon filament and the substrate according to the present invention.

FIG. 2C is a front side view for the structure illustrated in FIG. 2A.

### DETAILED DESCRIPTION OF THE INVENTION

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims. Embodiments of the present invention address the above-identified need by providing methods for the synthesis of high quality, large area graphene by CVD.

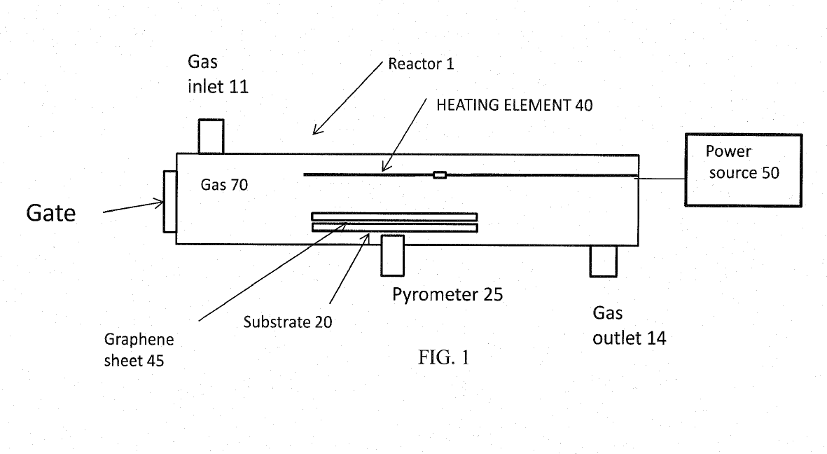

One aspects of the invention are directed to a system of forming a graphene film on a substrate. As illustrated in FIG. 1 of the present invention, the present invention includes the following elements.

A reactor 1 has a gas inlet 11 and a gas outlet 12.

A substrate 20 is placed in a reactor 30. The substrate 20 may be a metal substrate comprising Ni, Cu, Au, or the like, or a combination comprising at least one of the foregoing metals. Also the substrate 20 may be a dielectric substrate such as a silicon substrate with a thin layer of silicon dioxide, a glass substrate, a GaN substrate, a silica substrate, or the like. The substrate 20 may also be a dielectric substrate coated with a graphitizing catalyst film (not shown) such as Ni, Cu, Au, or the like, or a combination comprising at least one of the foregoing metals.

A heating element 40 is located in reactor 30. The heating element 40 is graphite or other carbon or carbon-containing filament, which is exposed to the same gases with the substrate. The heating element 40 is used as a heating source to heat the substrate 20 and also as a carbon source for forming a film on a substrate 20. The heating element 40 is powered on by a DC or AC power source 50 and the heating element 40 is heated.

The heating element 40 which is or is comprise of carbon can provide carbon for graphene deposition is driven at least in part by the inventors' observation that such a source can, under the right process conditions, produce gaseous reactants that can deposit graphene on a substrate.

One of the conditions is that gaseous carbon may be evaporated from the heating element 40 and deposit on substrate to form graphene. To make the process more controllable and efficient, reactant gas may be used. Hydrogen (H₂) gas, for example, is thought to react with solid carbon under elevated temperature by the following chemical reaction:

(m/2)H₂(g)+nC(s)→CₙHₘ(g). (1)

The evolved hydrocarbon gas, in turn, may react decompose onwith the hot substrate 20, which may play a role as catalyst, by the chemical reaction:

$${C}_{n} {H}_{m} ( g ) {\to }^{substrate} nC ( graphene ) + ( \frac{m}{2} ) {H}_{2} ( g ) \qquad ( 2 )$$

Thus, through the sequence of the chemical reactions (1) and (2), graphene is formed on the substrate by essentially transferring carbon from the carbon or carbon-containing heating element 40 to the surface of the substrate 20. Although the heating element 40 is depleted by the process, the rate of depletion is very slow and a substantial carbon source is likely to remain viable for a great multiplicity (e.g., many thousands) of deposition cycles. At the same time, the process does not require that a gaseous carbon source such as methane (CH₄) be introduced at high temperature and high partial pressure into the CVD reactor. The risk of explosion is thereby greatly reduced.

Another example is carbon dioxide (CO₂) by the following reactions:

$$\begin{matrix}{CO}_{2} ( g ) + C ( s ) \to 2 CO ( g ) . & ( 3 ) \\ nCO ( g ) {\to }^{substrate} ( \frac{n}{2} ) C ( graphene ) + ( \frac{n}{2} ) {CO}_{2} ( g ) & ( 4 )\end{matrix}$$

Another example is water vapor (H₂O) by the following reactions:

$$\begin{matrix}{H}_{2} O ( g ) + C ( s ) \to {H}_{2} ( g ) + CO ( g ) . & ( 5 ) \\ nCO ( g ) {\to }^{substrate} ( \frac{n}{2} ) C ( graphene ) + ( \frac{n}{2} ) {CO}_{2} ( g ) & ( 6 ) \\ ( m / 2 ) {H}_{2} ( g ) + nC ( s ) \to {C}_{n} {H}_{m} ( g ) . & ( 7 ) \\ {C}_{n} {H}_{m} ( g ) {\to }^{substrate} nC ( graphene ) + ( \frac{m}{2} ) {H}_{2} ( g ) & ( 8 )\end{matrix}$$

It should be noted that all these reactant gases need to be diluted with inert gas such as Ar, He, or N₂ to a concentration of 1 ppm to 20% in volume. The reaction pressure may be from 0.01 mTorr to 1 atm. The reaction temperature may be from 400 to 1400° C.

Process gases 70 inputs from the gas inlet 11 and after reaction, the exhaust outputs from the gas outlet 12.

Moreover, the process gas contains hydrogen, and by controlling feeding of hydrogen, small amount of carbon is transported to a surface of the substrate for graphene growth. Moreover, the process gas contains carbon dioxide, and by controlling feeding of carbon dioxide, small amount of carbon is transported to a surface of the substrate for graphene growth. Also, the process gas may contain water vapor, and by controlling feeding of water vapor, small amount of carbon is transported to a surface of the substrate for graphene growth.

The graphene sheet 45 can thus be formed on a substrate and/or on a graphitizing catalyst film on the substrate 20. The graphene sheet 45 can be used with the substrate, or the graphene sheet 45 can be separated from the substrate by a known technique.

Optionally, one or more process gases 70 may be introduced into the reactor for formation of the graphene film. The power source 50 can be DC or AC power source.

In the present invention, the number of the heating elements 40 is not confined to one. A plurality of heating elements 40 can be used as heating filaments. This is especially used for getting a large area graphene sheet.

Pyrometers 25 (or thermal couples) may be arranged near the substrate 20 for temperature detection and controlling.

The number of the pyrometers 25 (or thermal couples) are corresponding to that of the heating elements so that the temperature distribution is more uniform.

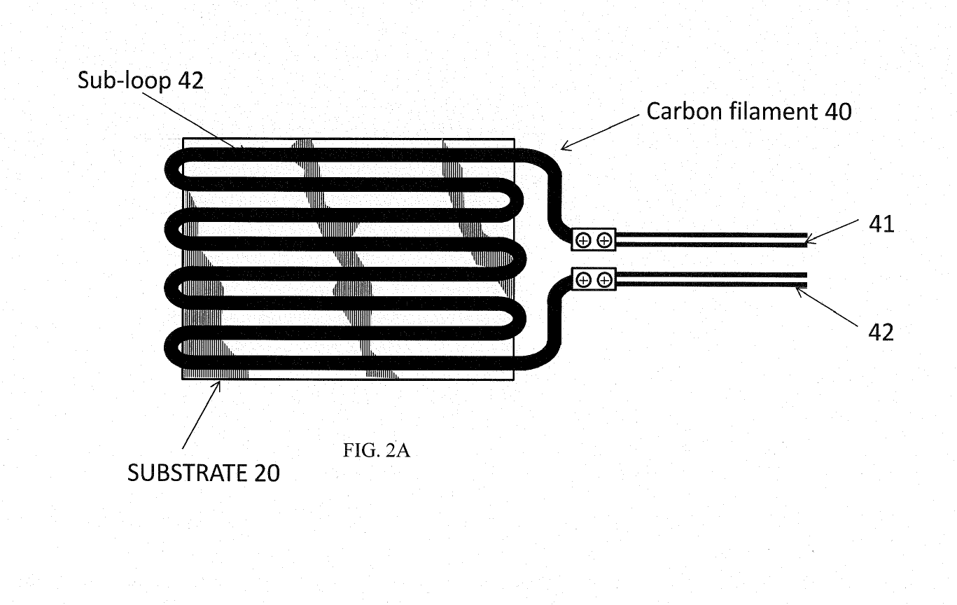

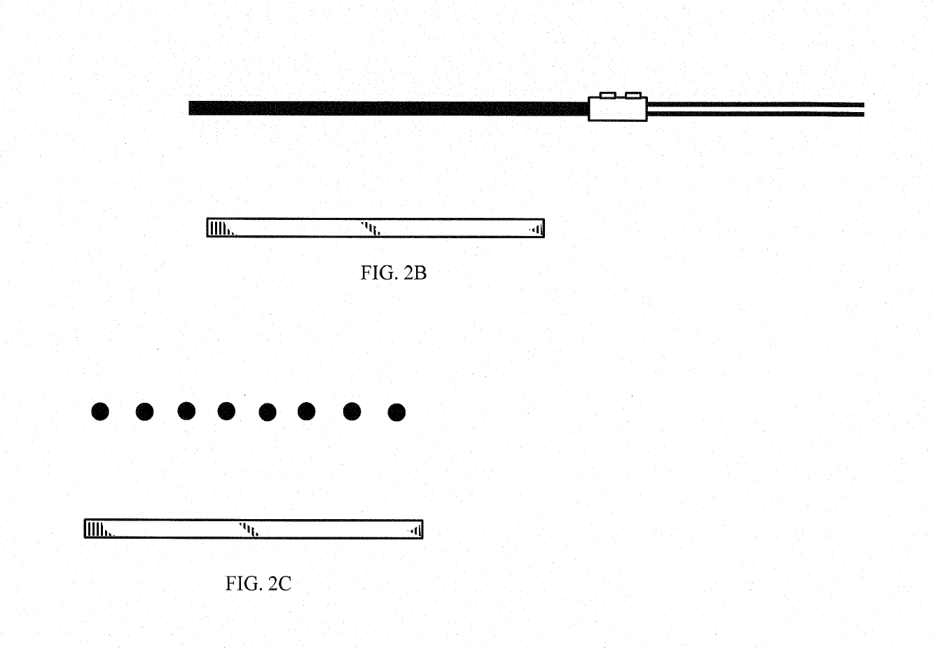

As illustrated in FIG. 2A, an upper view of the heating element 40 according to the present invention is illustrated.

It is illustrated that the carbon filament 40 is formed as a loop with two ends 41, 42 being connected to two electrodes of the power source 50. It is preferable that the carbon filament 40 is wounded with a plurality of sub-loops 42 for increasing the length of the whole carbon filament 40 so that the reaction area is increased. In this embodiment, the sub-loop 42 has an approximate U shape. All the sub-loops 42 are connected by one distal end of one loop is connected to a distal end of another loop, and the front end of the first loop and the distal end of the last loop are connected to the electrodes of the power source 50. The whole carbon filament 40 is formed to have a shape like a fork.

FIG. 2B shows a lateral side view of the carbon filament 50 and the substrate 20 according to the present invention; and FIG. 2C is a front side view for the structure illustrated in FIG. 2A.

In application, the graphene sheet can be applied in various fields and applications. The graphene sheet can be efficiently used as a transparent electrode since it has excellent conductivity and high uniformity. An electrode that is used on a solar cell substrate, or the like, is desirably transparent to allow light to penetrate therethrough. A transparent electrode formed of the graphene sheet has excellent conductivity and flexibility due to the flexibility of the graphene sheet. A flexible solar cell can be prepared by using a flexible plastic as a substrate and the graphene sheet as a transparent electrode. In addition, where the graphene sheet is used in the form of a conductive thin film in a display device, desired conductivity can be obtained using only a small amount of the graphene sheet and light penetration can thus be improved. In addition, the graphene sheet formed in the form of a tube can be used as an optical fiber, a hydrogen storage medium or a membrane that selectively allows hydrogen to penetrate.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A system for forming graphene on a substrate, comprising:
a reactor having a gas inlet and a gas outlet;
a substrate placed in the reactor;
a carbon-containing heating element located in reactor; which is exposed to the same atmosphere with the substrate; the carbon-containing heating element being used as a heating source to heat the substrate and also as a carbon source for forming a graphene film on a substrate;
at least one process gas inputted from the gas inlet and after reaction, exhausted process gas outputting from the gas outlet; and
wherein the carbon-containing heating element is powered on by a power source and the substrate is heated; by controlling feeding of process gas(es), carbon in the carbon-containing heating element is transported to a surface of the substrate for graphene growth; and thus, a graphene sheet is formed on the substrate.

2. The system as claimed in claim 1, wherein the carbon-containing heating element is graphite or carbon or carbon-containing filament.

3. The system as claimed in claim 1, wherein a graphitizing catalyst film is disposed on the substrate.

4. The system as claimed in claim 1, wherein the substrate is a metal substrate.

5. The system as claimed in claim 1, wherein the substrate is an dielectric substrate.

6. The system as claimed in claim 1, wherein the process gas contains hydrogen, and by controlling feeding of hydrogen, small amount of carbon is transported to a surface of the substrate for graphene growth.

7. The system as claimed in claim 1, wherein the process gas contains carbon dioxide, and by controlling feeding of carbon dioxide, small amount of carbon is transported to a surface of the substrate for graphene growth.

8. The system as claimed in claim 1, wherein the process gas contains water vapor, and by controlling feeding of water vapor, small amount of carbon is transported to a surface of the substrate for graphene growth.

9. The system as claimed in claim 1, wherein the process gas contains inert gas such as Ar, He, or N2 to dilute the reactant gas.

10. The system as claimed in claim 1, wherein more than one process gases are introduced into the reactor for the formation of the graphene film.

8. The system as claimed in claim 1, wherein the power source is a DC power source

9. The system as claimed in claim 1, wherein the power source is an AC power source.

10. The system as claimed in claim 1, wherein a plurality of heating elements are used.

11. The system as claimed in claim 1, wherein the carbon-containing heating element is formed as a loop with two ends being connected to two electrodes of the power source.

12. The system as claimed in claim 11, wherein the carbon-containing heating element is wounded with a plurality of sub-loops for increasing the length of the whole carbon filament so that the reaction area is increased.

13. The system as claimed in claim 12, wherein each sub-loop has an approximate U shape; all the sub-loops are connected by one distal end of one loop is connected to a distal end of another loop, and the front end of the first loop and the distal end of the last loop are connected to the electrodes of the power source.
